(19) United States
(12) Patent Application Publication
(10) Pub. No.: US 2011/0073928 A1
(43) Pub. Date: Mar. 31, 2011

(54) Non-Volatile Memory Devices Having Semiconductor Barrier Patterns and Methods of Forming Such Devices

(76) Inventors: ByungKyu Cho, Seoul (KR); Sunghoi Hur, Seoul (KR); Jaeduk Lee, Seongnam-si (KR); Jungdal Choi, Hwaseong-si (KR)

(21) Appl. No.: 12/894,844

(22) Filed: Sep. 30, 2010

(30) Foreign Application Priority Data
Sep. 30, 2009 (KR) 10-2009-0093301

(51) Int. Cl. H01L 29/788

(52) U.S. Cl. 257/316; 257/E29.3

(57) ABSTRACT

Provided are a non-volatile memory device and a method of forming the same. The non-volatile memory device includes: a tunnel insulation layer on a substrate; a floating gate on the tunnel insulation layer; a blocking insulation layer on the floating gate; a first barrier pattern, between the top of the floating gate and the blocking insulation layer, having a higher conduction band energy level than the floating gate; and a control gate on the blocking insulation layer.

### CROSS-REFERENCE TO RELATED APPLICATION

This U.S. non-provisional patent application claims priority under 35 U.S.C. §119 of Korean Patent Application No. 10-2009-0093301, filed on Sep. 30, 2009, the entire contents of which are hereby incorporated by reference as if set forth fully herein.

### BACKGROUND

The present disclosure relates to semiconductor devices and, more particularly, to non-volatile memory devices that have floating gates and to methods of forming such devices.

A non-volatile memory device retains the data stored therein even when the external power that is supplied to the device is cut off. A flash memory device having a floating gate is one example of a non-volatile memory device. Flash memory devices are highly-integrated devices that are obtained by combining the advantages of an Erasable Programmable Read Only Memory (EPROM) and an Electrically Erasable Programmable Read Only Memory (EEPROM). Flash memory devices are typically classified as either a NOR type or a NAND type flash memory device. The flash memory device may store data of logic 0 or logic 1 by storing charges in a floating gate or emitting the stored charges from the floating gate.

### SUMMARY

The present disclosure provides a non-volatile memory device that may reduce leakage current increases that may occur when electric fields are concentrated on the top of a floating gate.

Embodiments of the inventive concept provide non-volatile memory devices that include: a first insulation layer on a substrate; a floating gate on the first insulation layer; a second insulation layer on the floating gate; a first barrier pattern, between the top of the floating gate and the second insulation layer; and a control gate on the second insulation layer. The first barrier pattern has a higher conduction band energy level than the floating gate. The first insulation layer may be a tunnel insulation layer, and the second insulation layer may be a blocking insulation layer.

In some embodiments, the first semiconductor barrier pattern may extend on at least one side of the floating gate.

In other embodiments, a band gap of the floating gate may be broader than that of the first semiconductor barrier pattern.

In some embodiments, the floating gate may include germanium and the first semiconductor barrier pattern may include silicon.

In some embodiments, the floating gate and the first semiconductor barrier pattern may have the same conductivity type.

In some embodiments, the devices may further include a second semiconductor barrier pattern between the tunnel insulation layer and the floating gate.

In some embodiments, the second semiconductor barrier pattern may have a broader band gap than the floating gate.

In some embodiments, the second semiconductor barrier pattern may include silicon.

In some embodiments, the floating gate may be formed of an N-type semiconductor material and the first semiconductor barrier pattern may be formed of a P-type semiconductor material.

In some embodiments, the second semiconductor barrier pattern may be formed of a P-type semiconductor material.

In other embodiments of the inventive concept, methods of forming a non-volatile memory device include: forming a floating gate on a tunnel insulation layer; forming a first semiconductor barrier pattern on the floating gate; forming a blocking insulation layer on the floating gate and the first semiconductor barrier pattern; and forming a control gate on the blocking insulation layer.

In some embodiments, the forming of the first semiconductor barrier pattern may include: forming a first semiconductor barrier layer on the floating gate; and forming a first semiconductor barrier pattern by patterning the first semiconductor barrier layer.

In some embodiments, the forming of the first semiconductor barrier on the floating gate may include covering at least a portion of at least one side of the floating gate.

In some embodiments, the methods may further include forming a second semiconductor barrier pattern between the tunnel insulation layer and the floating gate.

In some embodiments, the second semiconductor barrier pattern may be formed of the same material as the first semiconductor barrier pattern.

In some embodiments, the second semiconductor barrier pattern may have the same conductivity type as the first semiconductor barrier pattern.

In some embodiments, the first semiconductor barrier pattern may be formed by implanting an impurity of a first conductivity type into the top and/or side of the floating gate.

In some embodiments, the impurity of the first conductivity type may be a P-type impurity; the floating gate may be formed of an N-type semiconductor; and the first semiconductor barrier pattern may be formed of a P-type semiconductor.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIGS. 1 through 7 are cross-sectional views and cross-sectional perspective views illustrating a non-volatile memory device and a method of forming the same according to a first embodiment of the inventive concept;

FIG. 8 is a graph illustrating an energy level of a conduction band of the non-volatile memory device according to the first embodiment of the inventive concept;

FIGS. 9 and 10 are cross-sectional views and cross-sectional perspective views illustrating a non-volatile memory device and a method of forming the same according to a second embodiment of the inventive concept;

FIGS. 11 through 18 are cross-sectional views and cross-sectional perspective views illustrating a non-volatile memory device and a method of forming the same according to a third embodiment of the inventive concept;

FIGS. 19 through 25 are cross-sectional views and cross-sectional perspective views illustrating a non-volatile memory device and a method of forming the same according to a fourth embodiment of the inventive concept;

FIG. 26 is a graph illustrating an energy level of a conduction band of the non-volatile memory device according to the fourth embodiment of the inventive concept;

FIGS. 27 and 28 are cross-sectional views and cross-sectional perspective views illustrating a non-volatile memory device and a method of forming the same according to a fifth embodiment of the inventive concept;

FIGS. 29 through 36 are cross-sectional views and cross-sectional perspective views illustrating a non-volatile memory device and a method of forming the same according to a sixth embodiment of the inventive concept;

FIGS. 37 through 42 are cross-sectional views and cross-sectional perspective views illustrating a non-volatile memory device and a method of forming the same according to a seventh embodiment of the inventive concept;

FIG. 43 is a block diagram illustrating an electronic system including a non-volatile memory device according to embodiments of the inventive concept; and

FIG. 44 is a block diagram illustrating a memory card including a non-volatile memory device according to an embodiment of the inventive concept.

### DETAILED DESCRIPTION OF THE EMBODIMENTS

Advantages and features of the inventive concept, and implementation methods thereof will be clarified through following embodiments described with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. The inventive concept is defined by the scope of the claims appended hereto. Like reference numerals refer to like elements throughout.

In the specification, when it is mentioned that a certain material layer such as a conductive layer, a semiconductor layer, or an insulation layer is disposed “on” another material or a substrate, the certain material layer may be directly formed on the another material layer or the substrate, or another material layer may be interposed therebetween. Also, though terms like a first, a second, and a third are used to describe a material layer and an operation in various embodiments of the inventive concept, they are merely used to distinguish a specific material layer or operation from other material layers or operations and thus are not limited to these terms.

In the following description, the technical terms are used only for explaining a specific exemplary embodiment while not limiting the inventive concept. The terms of a singular form may include plural forms unless referred to the contrary. The meaning of “comprises” and/or “comprising” specifies a property, a region, a fixed number, a step, a process, an element, a component and/or the like but does not exclude other properties, regions, fixed numbers, steps, processes, elements, components, etc.

Additionally, the embodiment in the detailed description will be described with cross-sectional views as ideal exemplary views of the inventive concept. In the figures, the dimensions of layers and regions are exaggerated for clarity of illustration. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. For example, an etched region illustrated as a rectangle may have rounded or curved features. Areas exemplified in the drawings have general properties, and are used to illustrate a specific shape of a semiconductor package region. Thus, this should not be construed as limited to the scope of the inventive concept.

Hereinafter, non-volatile memory devices and methods of forming such devices according to embodiments of the inventive concept will be described in more detail with reference to the drawings.

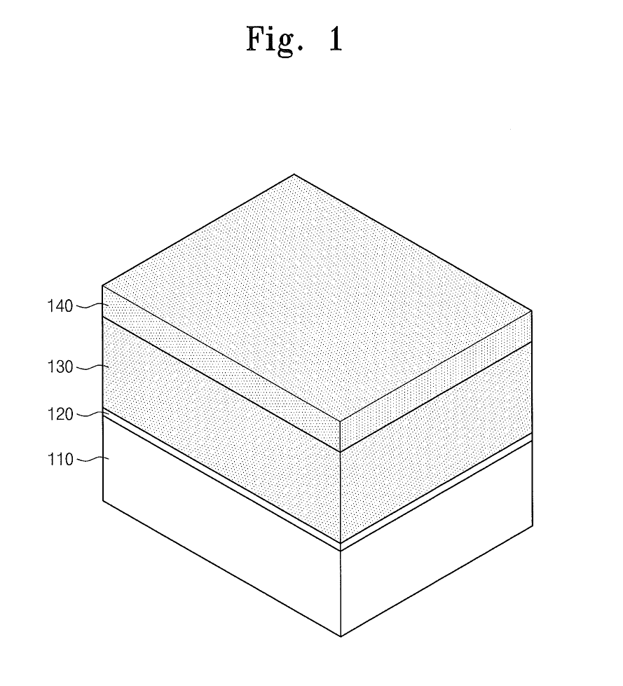

FIGS. 1 through 7 illustrate a non-volatile memory device and a method of forming the same according to a first embodiment of the inventive concept.

Referring to FIG. 1, a first insulation layer 120 may be formed on a substrate 110. The substrate 110 may comprise, for example, an arbitrary semiconductor based structure having a silicon (or other semiconductor) surface. This semiconductor based structure may mean a silicon epitaxial layer supported by silicon, a silicon-on-insulator (SOI), or a semiconductor structure. The first insulation layer 120 may comprise a silicon oxide layer. The first insulation layer 120 may be formed using a thermal oxidation process. A first conductive layer 130 may be formed on the first insulation layer 120. The first conductive layer 130 may be an N-type silicon layer. The first conductive layer 130 may be formed by, for example, chemical vapor deposition (CVD). A first semiconductor barrier layer 140 may be formed on the first conductive layer 130. The first semiconductor barrier layer 140 may be a P-type silicon layer. The first semiconductor barrier layer 140 may also be formed by a CVD process.

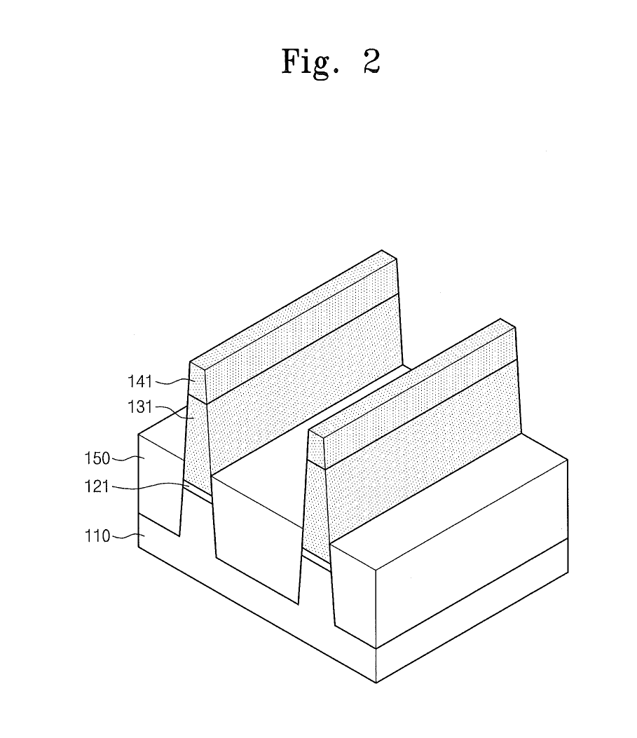

Referring to FIG. 2, the substrate 110, the first insulation layer 120, the first conductive layer 130, and the first semiconductor barrier layer 140 are patterned. A tunnel insulation layer 121 (which is formed from the first insulation layer 120), a preliminary floating gate 131 (which is formed from the first conductive layer 130), and a preliminary first semiconductor barrier pattern 141 (which is formed from the first semiconductor barrier layer 140) are formed by the patterning. A device isolation layer 150 may be formed in a recess region formed by the patterning. The device isolation layer 150 may define an active region. The device isolation layer 150 may be, for example, a silicon oxide layer which is formed using a high density plasma CVD method with an excellent gap-fill property.

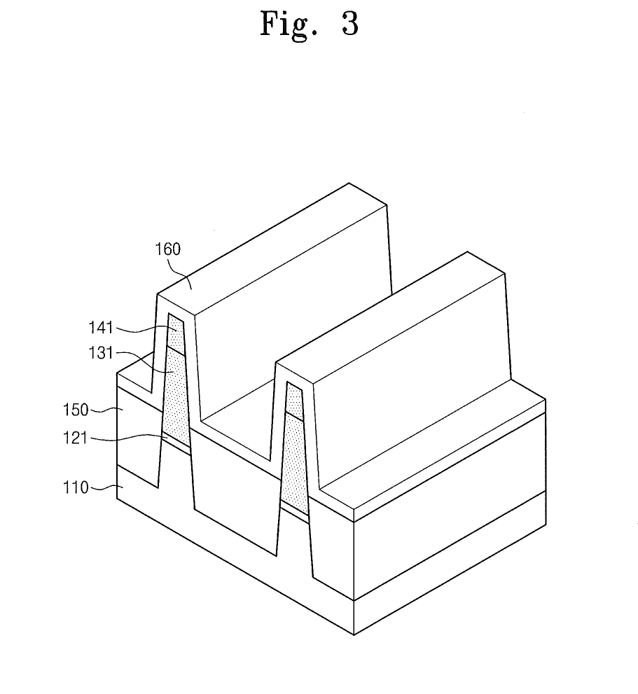

Referring to FIG. 3, a second insulation layer 160 may be formed on the device isolation layer 150, the preliminary floating gate 131, and the preliminary first semiconductor barrier pattern 141. The second insulation layer 160 may be, for example, an oxide layer, a nitride layer, or a stacked layer structure thereof. In some embodiments, the second insulation layer 160 may be an Oxide-Nitride-Oxide (ONO) layer. In other embodiments, the second insulation layer 160 may include a high-dielectric constant (hereinafter, referred to as high-k) layer having a dielectric constant that is higher than the dielectric constant of a nitride layer. For example, the second insulation layer 160 may include a metal oxide layer, or a high-k layer. For example, the second insulation layer 160 may include an aluminum oxide layer or a hafnium oxide layer. The second insulation layer 160 may be uniformly deposited on an uneven side of the preliminary floating gate 131.

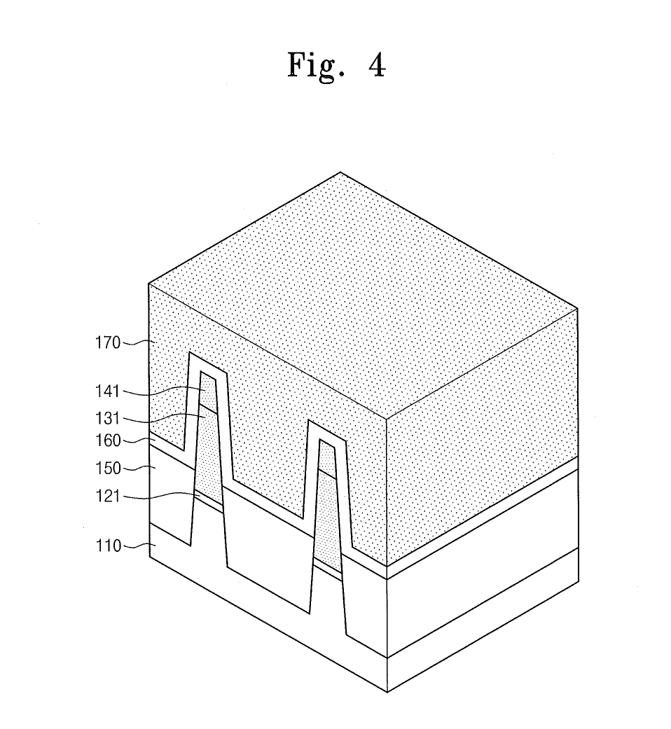

Referring to FIG. 4, a second conductive layer 170 may be formed on the second insulation layer 160. The second conductive layer 170 may comprise, for example, a doped polysilicon layer or a doped polycide layer.

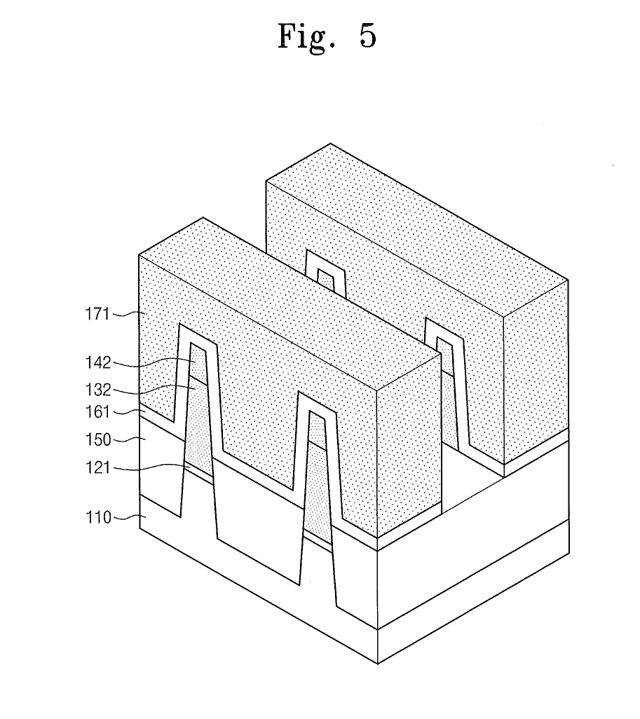

Referring to FIG. 5, the preliminary floating gate 131, the preliminary first semiconductor barrier pattern 141, the second insulation layer 160, and the second conductive layer 170 may be patterned. A floating gate 132, a first semiconductor barrier pattern 142, a blocking insulation layer 161, and a control gate 171 may be formed by the patterning.

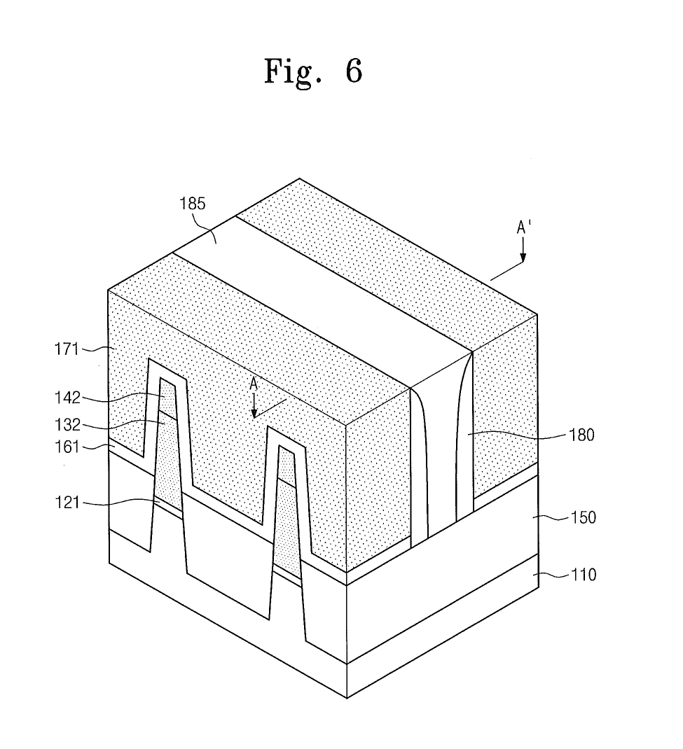

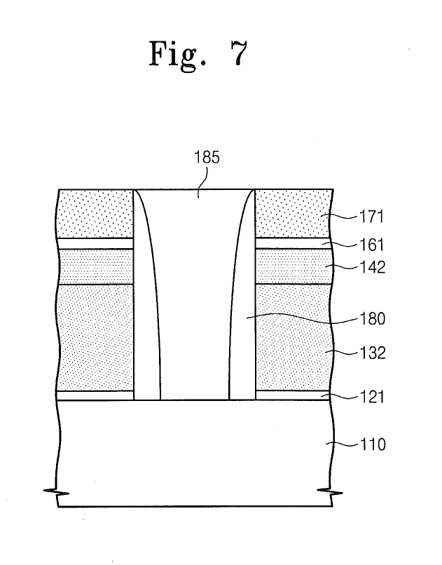

Referring to FIGS. 6 and 7, an insulation spacer 180 may be formed on the sidewall of the recessed region that is formed by the patterning of the preliminary floating gate 131, the preliminary first semiconductor barrier pattern 141, the second insulation layer 160, and the second conductive layer 170. The insulation spacer 180 may comprise, for example, silicon nitride. A third insulation layer 185 may be formed in the remainder of the recessed region. The third insulation layer 185 may be a silicon oxide layer. FIG. 7 is a sectional view taken along the line A-A′ of FIG. 6.

The non-volatile memory device according to the first embodiment of the inventive concept provides the first semiconductor barrier pattern 142 between the floating gate 132 and the blocking insulation layer 161. As the size of individual flash memory cells are further reduced to provide flash memory devices having increased integration density, the width of the top portion of the floating gate may be narrowed. As a result, electric fields that are generated by the control gate may be concentrated on this narrowed top portion of the floating gate, and hence leakage current can be increased. With the non-volatile memory device according to the first embodiment of the inventive concept, the floating gate 132 may be formed of an N-type semiconductor and the first semiconductor barrier pattern 142 may be formed of a P-type semiconductor on the floating gate 132. The first semiconductor barrier pattern 142 (which is a P-type semiconductor) has a conduction band of a higher energy level than the floating gate 132 (which is an N-type semiconductor). Accordingly, the possibility of back tunneling to the blocking insulation layer 161 may be lowered by increasing the tunneling length. In this manner, electric fields may be concentrated on the top surface of the floating gate 132 such that the tendency for increased leakage currents through the blocking insulation layer 161 can be reduced and/or alleviated.

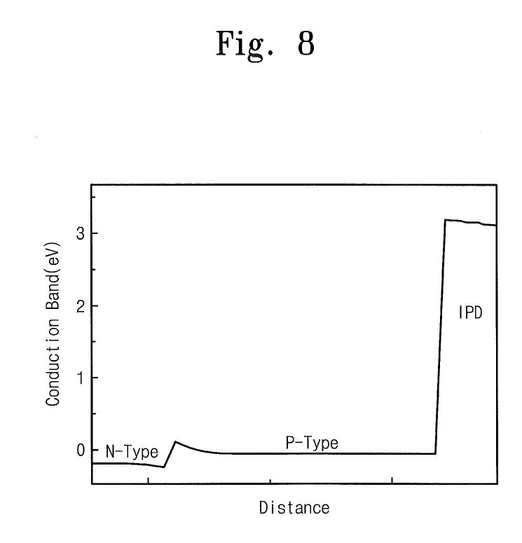

FIG. 8 is a graph illustrating an energy level of a conduction band of the non-volatile memory devices according to the first embodiment of the inventive concept. The first semiconductor barrier pattern 142 of a P-type semiconductor has a conduction band of a higher energy level than the N-type semiconductor floating gate 132. Accordingly, back tunneling through the blocking insulation layer 161 can be reduced.

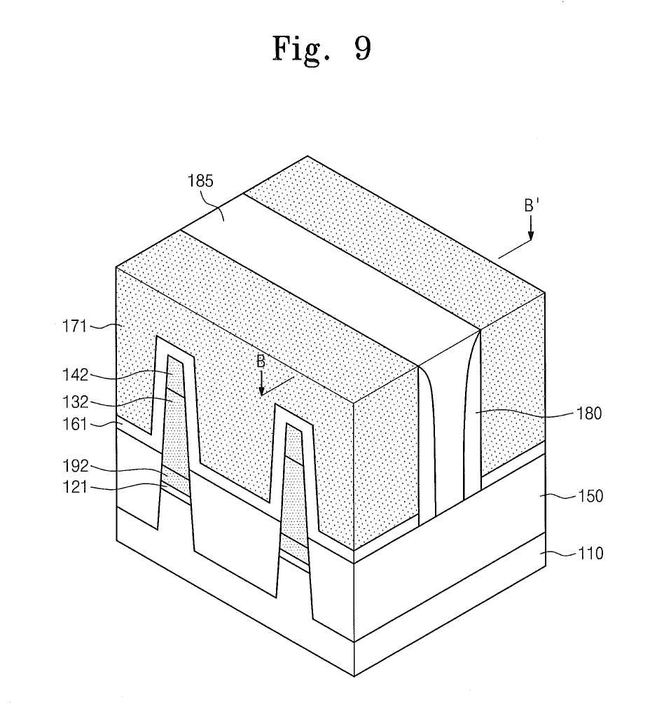

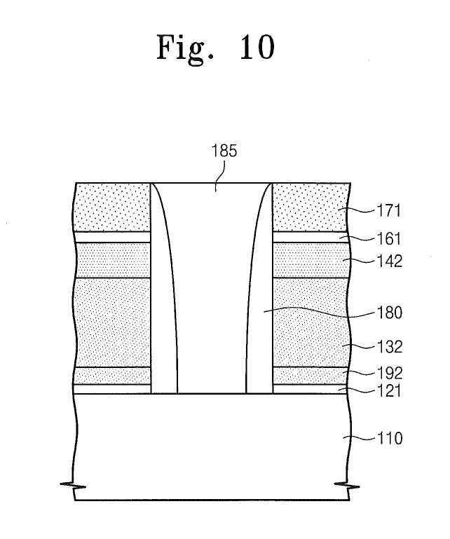

FIG. 9 is a perspective cross-sectional view of a non-volatile memory device and a method of forming the same according to a second embodiment of the inventive concept. FIG. 10 is a sectional view taken along the line B-B′ of FIG. 9. Except for a difference of the second semiconductor barrier pattern, this embodiment is similar to the first embodiment that is discussed above with reference to FIGS. 1-7. Accordingly, for conciseness of description, further discussion of overlapping technical features will be omitted.

Referring to FIGS. 9 and 10, a first semiconductor barrier pattern 142 is provided on the floating gate 132. The floating gate 132 may be an N-type silicon layer. The first semiconductor barrier pattern 142 may be a P-type silicon layer. A second semiconductor barrier pattern 192 is provided between the tunnel insulation layer 121 and the floating gate 132. The second semiconductor barrier pattern 192 may also be a P-type silicon layer. The second semiconductor barrier layer 192 may be formed by a CVD process. The non-volatile memory device according to the second embodiment of the inventive concept may have an energy band of a well formed by the first semiconductor barrier pattern 142 and the second semiconductor barrier pattern 192. Accordingly, tunneling length of charges stored in the floating gate 132 may be increased in a direction of the blocking insulation layer 161 and a direction of the tunnel insulation layer 121. Accordingly, charges stored in the floating gate 132 may be more stably stored in the floating gate 132. Thus, the reliability of the memory device can be improved.

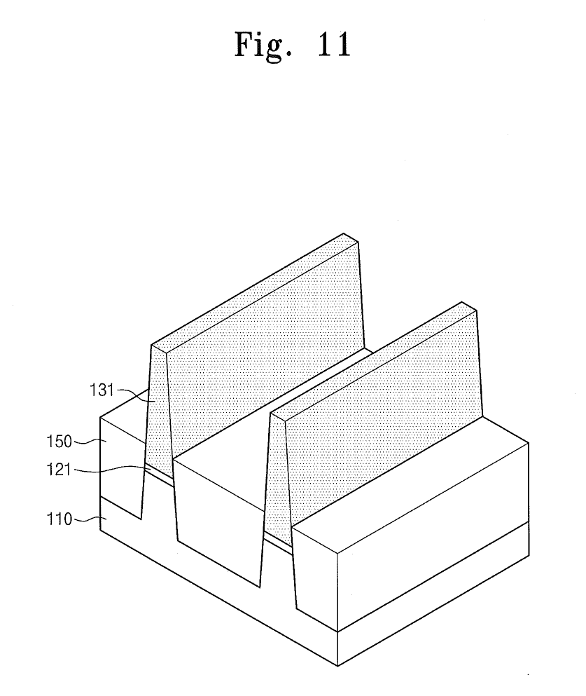

FIGS. 11 through 18 illustrate a non-volatile memory device and a method of forming the same according to a third embodiment of the inventive concept. Except for a difference of the first semiconductor barrier pattern, this embodiment is similar to the first embodiment discussed above with reference to FIGS. 1-7. Accordingly, for conciseness of description, further discussion of overlapping technical features will be omitted.

Referring to FIG. 11, a tunnel insulation layer 121, a preliminary floating gate 131, and a device isolation layer 150 may be formed on a substrate 110. The preliminary floating gate 131 may be formed in the same manner of the first embodiment. The preliminary floating gate 131 may be formed of a N-type silicon.

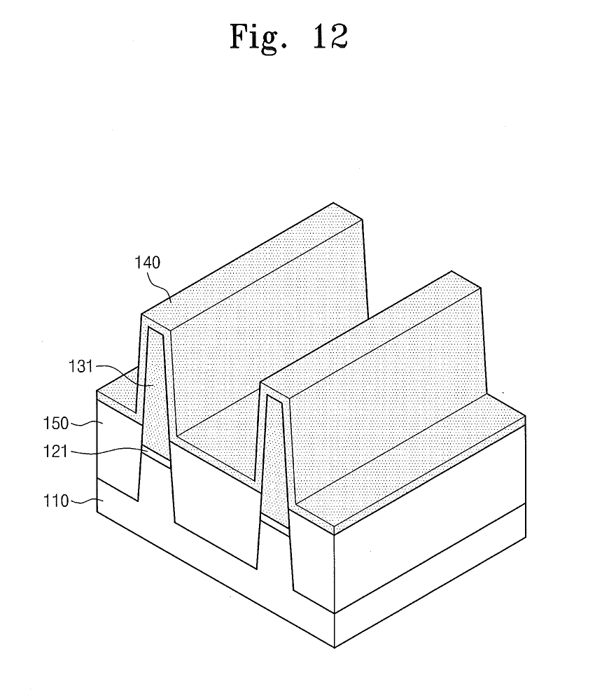

Referring to FIG. 12, a first semiconductor barrier layer 140 is provided on the preliminary floating gate 131. The first semiconductor barrier layer 140 may be a P-type silicon layer. The first semiconductor barrier layer 140 may be formed by a CVD process.

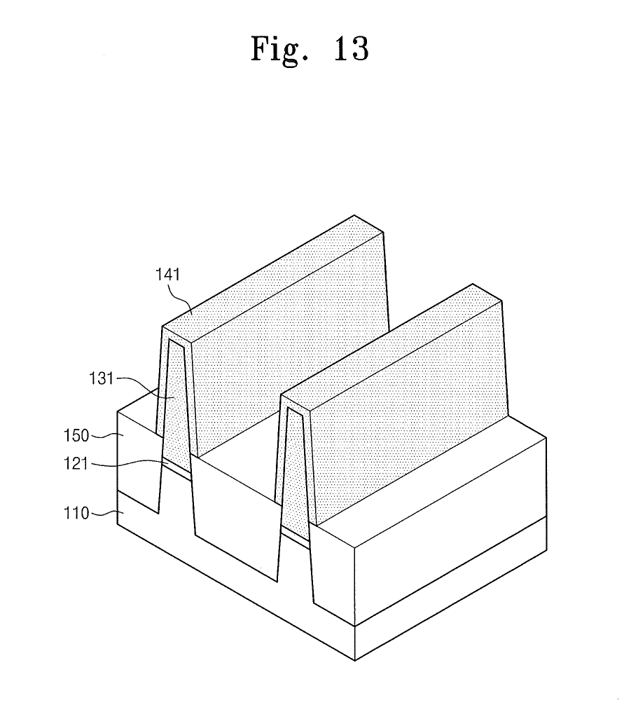

Referring to FIG. 13, the first semiconductor barrier layer 140 may be patterned. A preliminary first semiconductor barrier pattern 141 is formed by the patterning. The preliminary first semiconductor barrier pattern 141 may partially cover the top and sidewall of the preliminary floating gate 131.

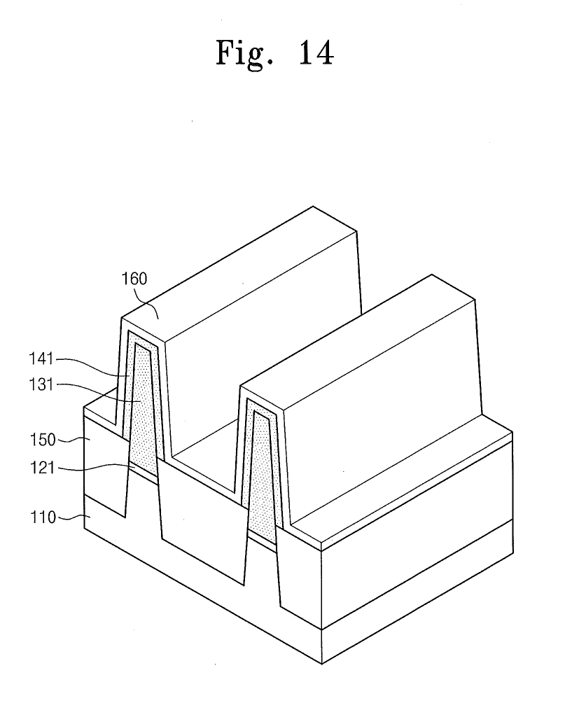

Referring to FIG. 14, a second insulation layer 160 may be formed on the device isolation layer 150, the preliminary floating gate 131, and the preliminary first semiconductor barrier pattern 141. The second insulation layer 160 may be, for example, an oxide layer, a nitride layer, or a stacked layer structure thereof. In some embodiments, the second insulation layer 160 may be an ONO layer. In other embodiments, the second insulation layer 160 may include a high-k layer having a higher dielectric constant than a nitride layer. For example, the second insulation layer 160 may include a metal oxide layer having a high-k. For example, the second insulation layer 160 may include an aluminum oxide layer or a hafnium oxide layer. The second insulation layer 160 may be uniformly deposited on an uneven side of the preliminary floating gate 131.

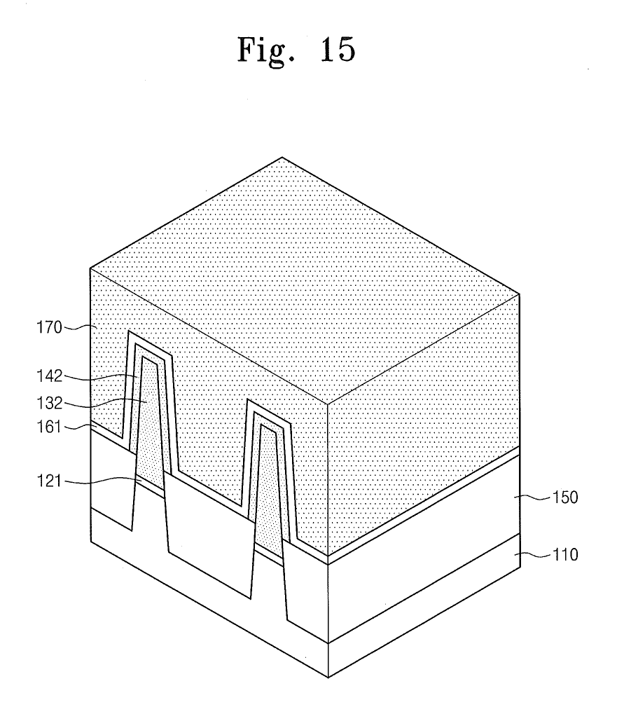

Referring to FIG. 15, a second conductive layer 170 may be formed on the second insulation layer 160. The second conductive layer 170 may comprise, for example, a doped polysilicon layer or a doped polycide layer.

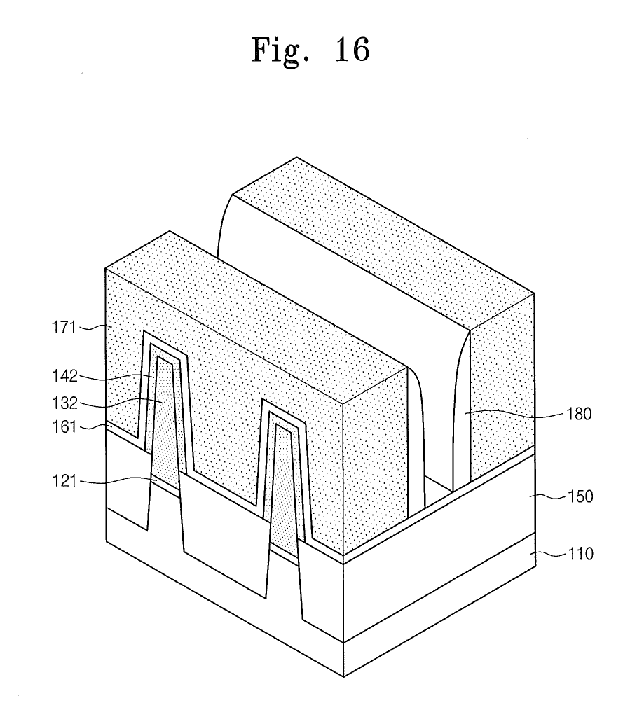

Referring to FIG. 16, the preliminary floating gate 131, the preliminary first semiconductor barrier pattern 141, the second insulation layer 160, and the second conductive layer 170 may be patterned. A floating gate 132, a first semiconductor barrier pattern 142, a blocking insulation layer 161, and a control gate 171 may be formed by the patterning. An insulation spacer 180 may be formed on the sidewall of the recessed region formed by the patterning. The insulation spacer 180 may be formed of a silicon nitride.

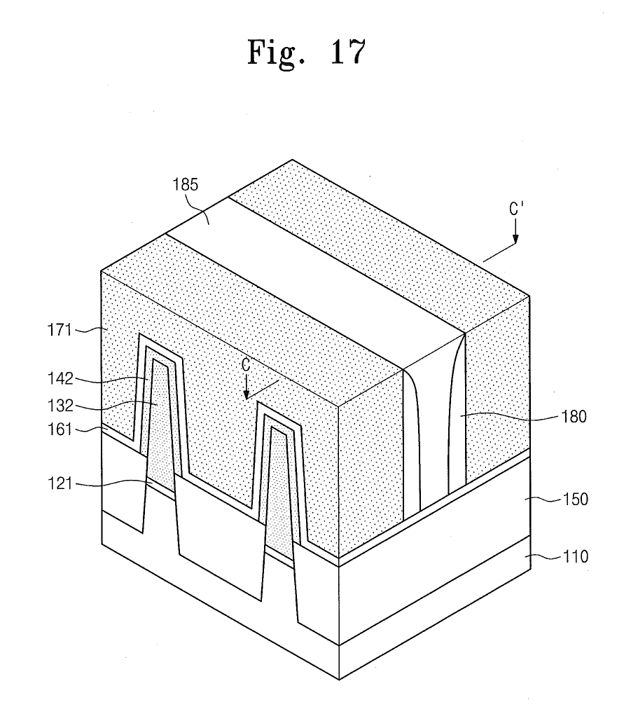

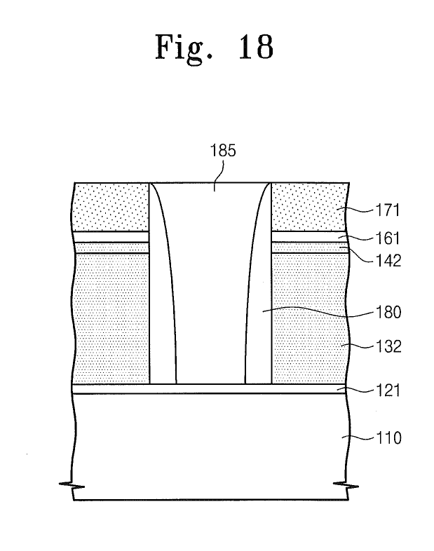

Referring to FIG. 17, a third insulation layer 185 may be formed in the recessed region between the insulation spacers 180. The third insulation layer 185 may be a silicon oxide layer. FIG. 18 is a sectional view taken along the line C-C′ of FIG. 17.

In the non-volatile memory device according to the third embodiment of the inventive concept, the first semiconductor barrier pattern 142 extends on at least a portion of the top and sidewall of the floating gate 132. Accordingly, the possibility that charges will back tunnel from the floating gate 132 to the blocking insulation layer 161 may be reduced by increasing the tunneling length as the electric fields may be concentrated on the top surface of the floating gate 132 such that leakage current increase through the blocking insulation layer 61 can be reduced and/or alleviated.

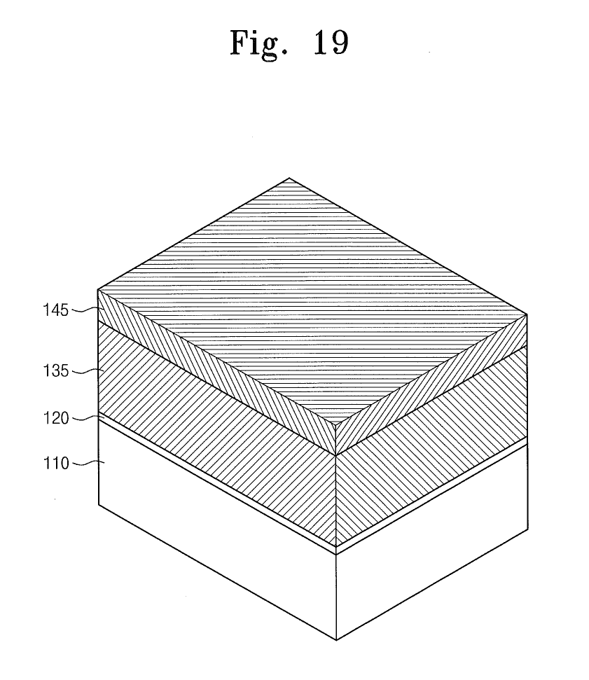

FIGS. 19 through 25 illustrate a non-volatile memory device and a method of forming the same according to a fourth embodiment of the inventive concept.

Referring to FIG. 19, a first insulation layer 120 may be formed on a substrate 110. The substrate 110 may be any of the substrates discussed above with respect to the first embodiment of FIGS. 1-7. A first conductive layer 135 may be formed on the first insulation layer 120. The first conductive layer 135 may be a germanium layer doped with an impurity. The first conductive layer 135 may be formed, for example, by a CVD process. A first conductive barrier layer 145 may be formed on the first conductive layer 135. The first semiconductor barrier layer 145 may be a semiconductor layer having a broader band gap than the first conductive layer 135. The first semiconductor barrier layer 145 may be a silicon layer doped with an impurity. The first conductive barrier layer 135 and the first semiconductor barrier layer 145 may be doped to have the same conductivity type. The first semiconductor barrier layer 145 may be formed, for example, by a CVD process.

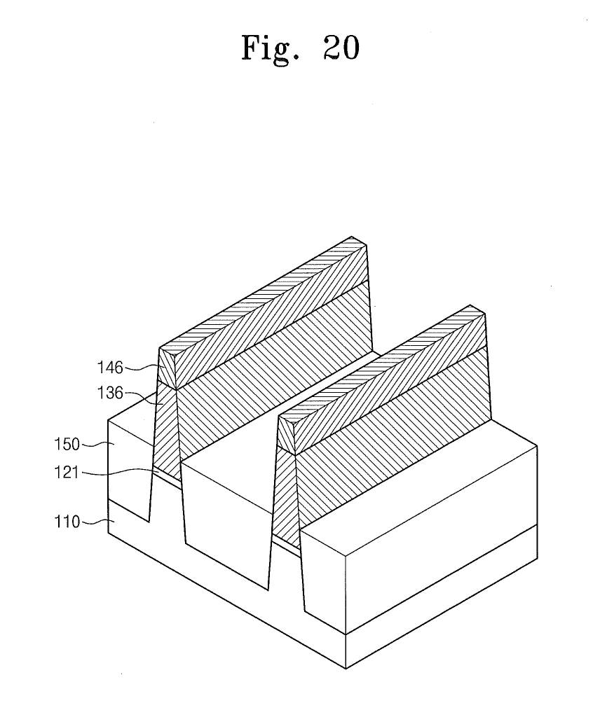

Referring to FIG. 20, the substrate 110, the first insulation layer 120, the first conductive layer 135, and the first semiconductor barrier layer 145 are patterned. A tunnel insulation layer 121, a preliminary floating gate 136, and a preliminary first semiconductor barrier pattern 146 are formed by the patterning. A device isolation layer 150 may be formed in the recessed region that is formed by the patterning. The device isolation layer 150 may define an active region.

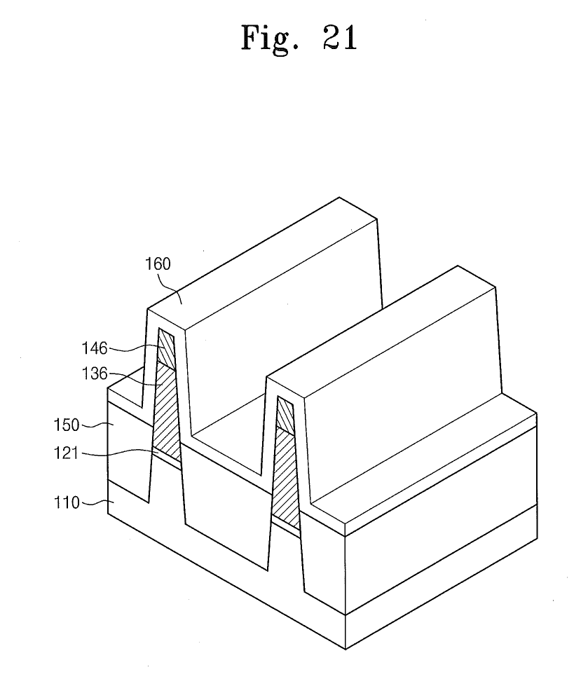

Referring to FIG. 21, a second insulation layer 160 may be formed on the device isolation layer 150, the preliminary floating gate 136, and the preliminary first semiconductor barrier pattern 146. The second insulation layer 160 may be an oxide layer, a nitride layer, or a staked layer structure thereof. In some embodiments, the second insulation layer 160 may be an ONO layer. In other embodiments, the second insulation layer 160 may include a high-k layer having a higher dielectric constant than a nitride layer. For example, the second insulation layer 160 may include a metal oxide layer having a high-k. For example, the second insulation layer 160 may include an aluminum oxide layer or a hafnium oxide layer. The second insulation layer 160 may be uniformly deposited on an uneven side of the preliminary floating gate 136.

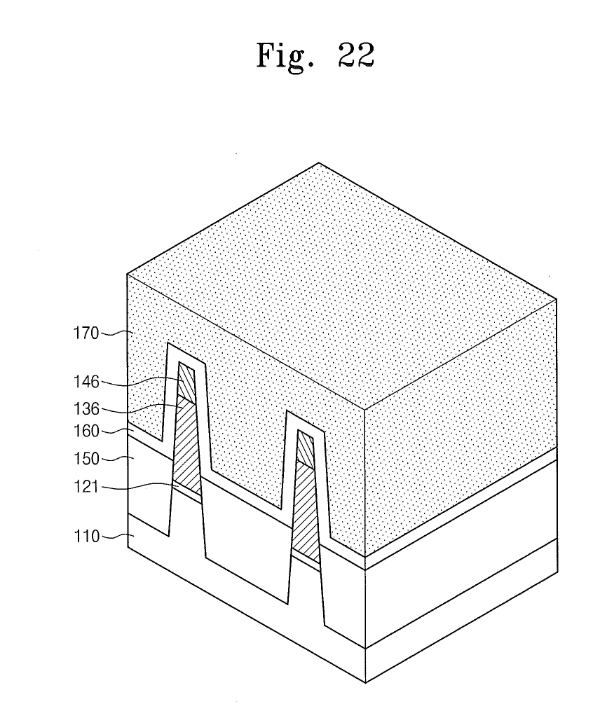

Referring to FIG. 22, a second conductive layer 170 may be formed on the second insulation layer 160. The second conductive layer 170 may be formed of a doped polysilicon layer or a doped polycide layer.

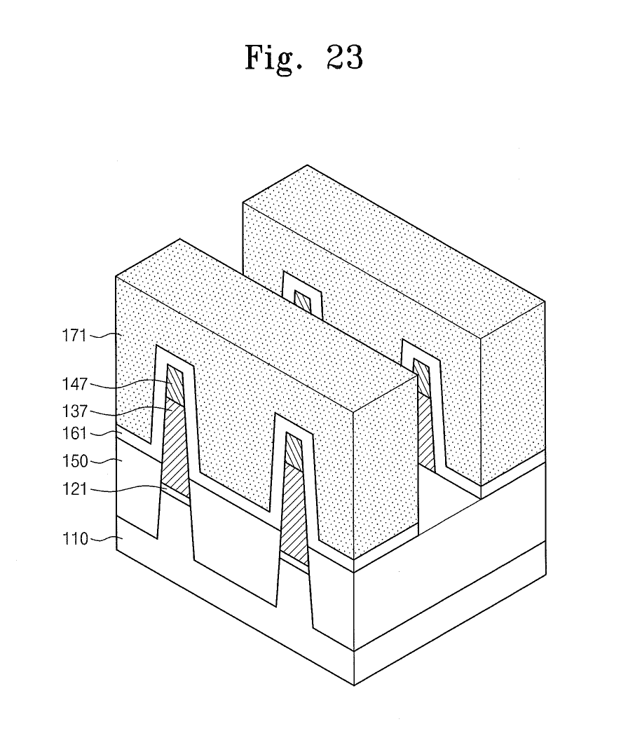

Referring to FIG. 23, the preliminary floating gate 136, the preliminary first semiconductor barrier pattern 146, the second insulation layer 160, and the second conductive layer 170 may be patterned. A floating gate 137, a first semiconductor barrier pattern 147, a blocking insulation layer 161, and a control gate 171 may be formed by the patterning.

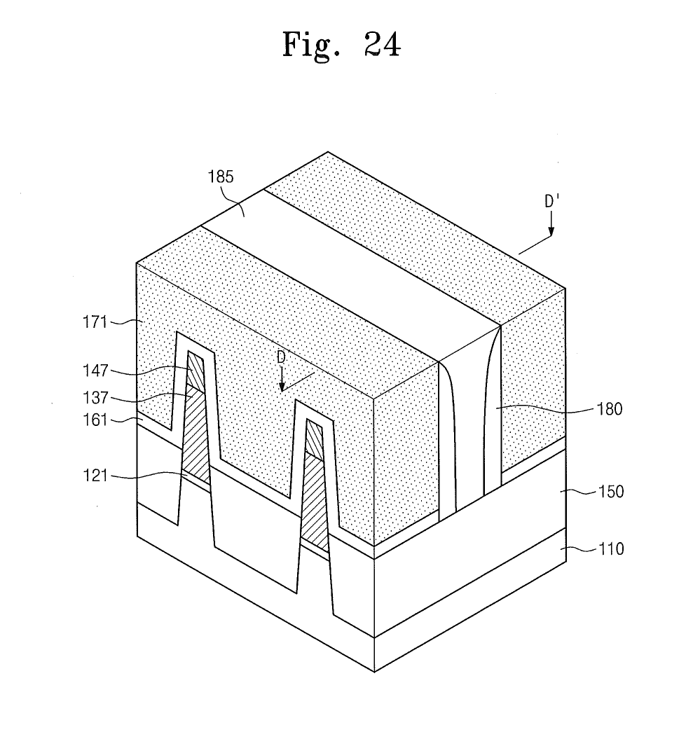

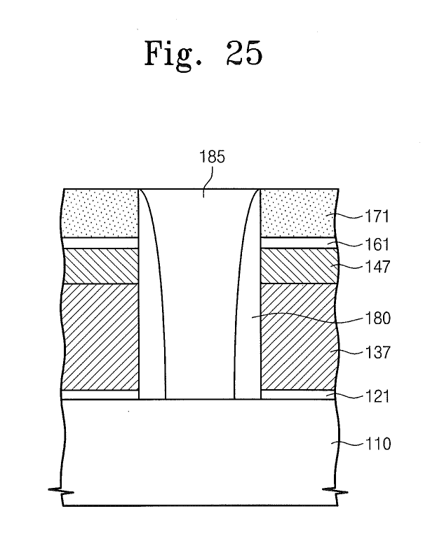

Referring to FIGS. 24 and 25, an insulation spacer 180 may be formed on the sidewall of the recessed region formed by the patterning. The insulation spacer 180 may be formed of a silicon nitride. A third insulation layer 185 may be formed in the remainder of the recessed region. The third insulation layer 185 may be a silicon oxide layer. FIG. 25 is a sectional view taken along the line D-D′ of FIG. 24.

The non-volatile memory device according to the fourth embodiment of the inventive concept provides the first semiconductor barrier pattern 147 between the floating gate 137 and the blocking insulation layer 161. In the non-volatile memory device according to the fourth embodiment of the inventive concept, the floating gate 137 is formed of germanium and the first semiconductor barrier pattern 147 is formed of silicon. Silicon has a broader energy band gap than germanium. When it is doped with an impurity of the same conductive type, the first semiconductor barrier pattern 147 formed of silicon has a conduction band of a higher energy level than the floating gate 137 formed of germanium. Accordingly, the possibility of back tunneling to the blocking insulation layer 161 may be lowered by increasing the tunneling length. As such, electric fields may be concentrated on the top surface of the floating gate 137 such that leakage current increase through the blocking insulation layer 161 can be reduced and/or alleviated.

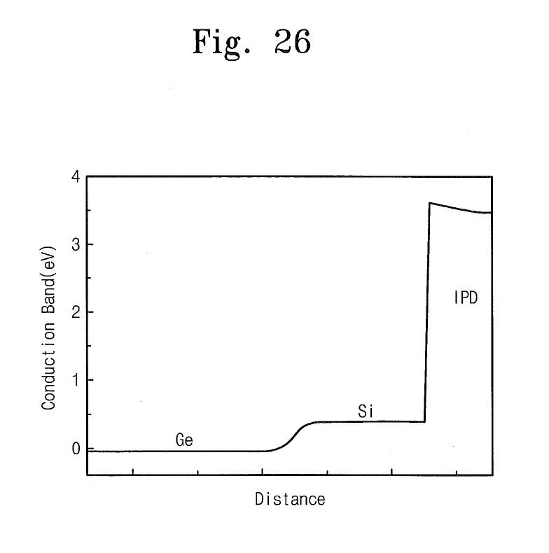

FIG. 26 is a graph illustrating an energy level of a conduction band of a non-volatile memory device according to the fourth embodiment of the inventive concept. The first semiconductor barrier pattern 147 formed of silicon has a conduction band of a higher energy level than the floating gate 137 formed of germanium. Accordingly, back tunneling through the blocking insulation layer 161 can be reduced.

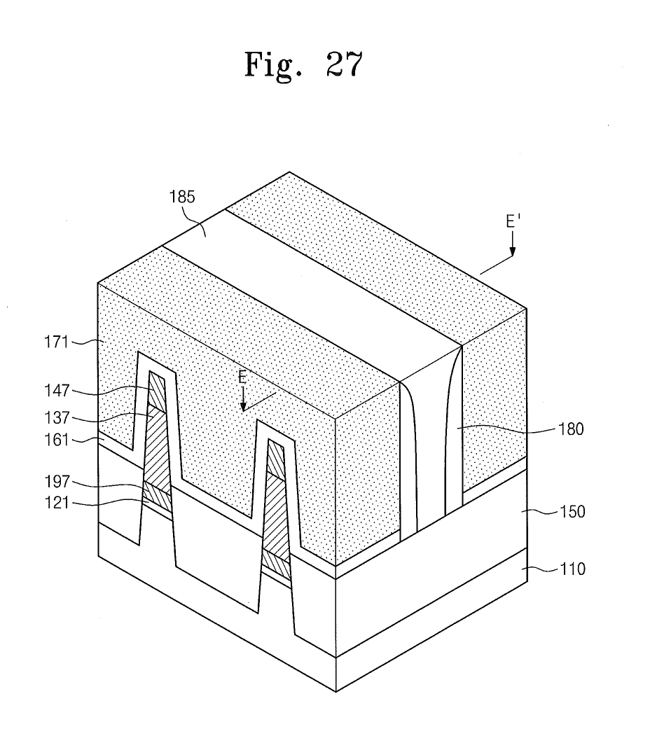

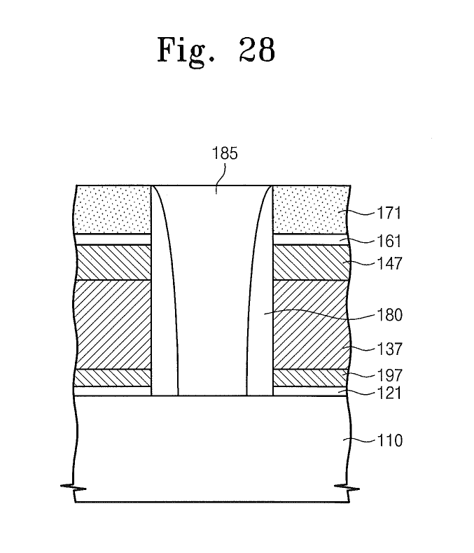

FIG. 27 is a perspective cross-sectional view illustrating a non-volatile memory device and a method of forming the same according to a fifth embodiment of the inventive concept. FIG. 28 is a sectional view taken along the line E-E′ of FIG. 27. Except for a difference of the second semiconductor barrier pattern, this embodiment is similar to the fourth embodiment that is described above with respect to FIGS. 19-25. Accordingly, for conciseness of description, further discussion of overlapping technical features will be omitted.

Referring to FIGS. 27 and 28, a first semiconductor barrier pattern 147 is provided on a floating gate 137. The floating gate 137 may be a germanium layer doped with an impurity. The first semiconductor barrier layer 147 may be a silicon layer doped with an impurity. A second semiconductor barrier pattern 197 is provided between a tunnel insulation layer 121 and the floating gate 137. The second semiconductor barrier layer 197 may be a silicon layer doped with an impurity. The second semiconductor barrier layer 197 may be formed by a CVD process. The non-volatile memory device according to the fifth embodiment of the inventive concept may have an energy band of a well formed by the first semiconductor barrier pattern 147 and the second semiconductor barrier pattern 197. Accordingly, tunneling length of charges stored in the floating gate 137 may be increased in a direction of the blocking insulation layer 161 and a direction of the tunnel insulation layer 121. Accordingly, charges stored in the floating gate 137 may be more stably stored in the floating gate 137. Thus, reliability of the memory device can be improved.

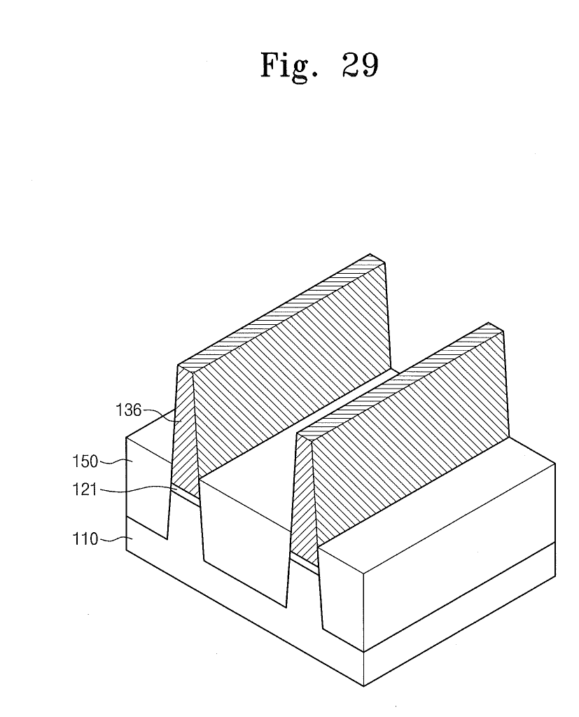

FIGS. 29 through 36 illustrate a non-volatile memory device and a method of forming the same according to a sixth embodiment of the inventive concept. Except for a difference of the first semiconductor barrier pattern formation, this embodiment is similar to the fourth embodiment that is described above with respect to FIGS. 19-25. Accordingly, for conciseness of description, further discussion of overlapping technical features will be omitted.

Referring to FIG. 29, a tunnel insulation layer 121, a preliminary floating gate 136, and a device isolation layer 150 may be provided on a substrate 110. The preliminary floating gate 136 may be formed in the same manner as discussed above with respect to the fourth embodiment. The preliminary floating gate 136 may be a germanium layer doped with an impurity.

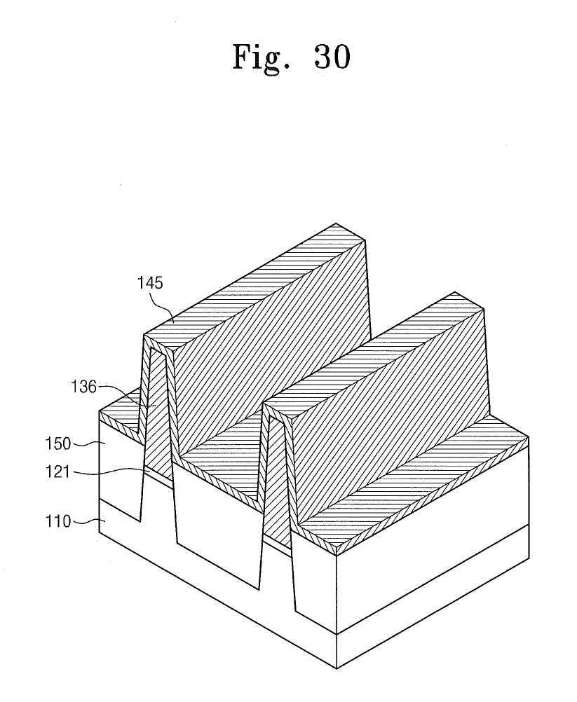

Referring to FIG. 30, a first semiconductor barrier pattern 145 is formed on the preliminary floating gate 136. The first semiconductor barrier layer 145 may be a silicon layer doped with an impurity. The first semiconductor barrier layer 145 may be formed, for example, by a CVD process.

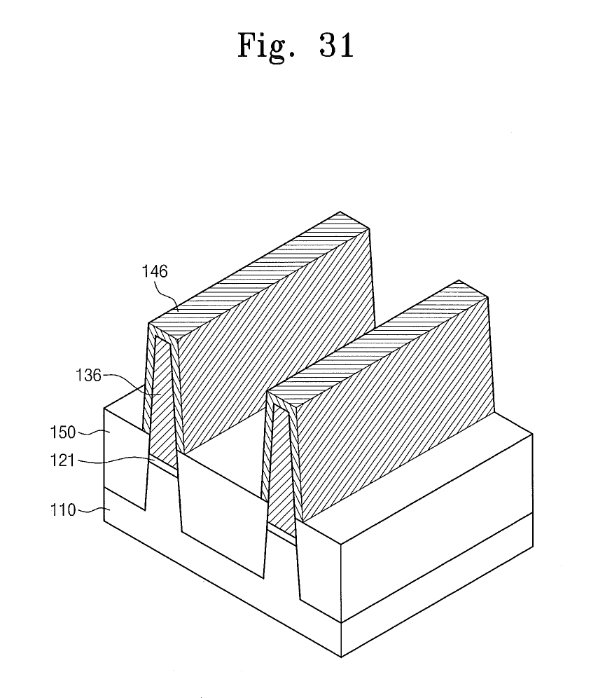

Referring to FIG. 31, the first semiconductor barrier layer 145 may be patterned. A preliminary first semiconductor barrier pattern 146 is formed by the patterning. The preliminary first semiconductor barrier pattern 146 may partially cover the top and sidewall of the preliminary floating gate 136.

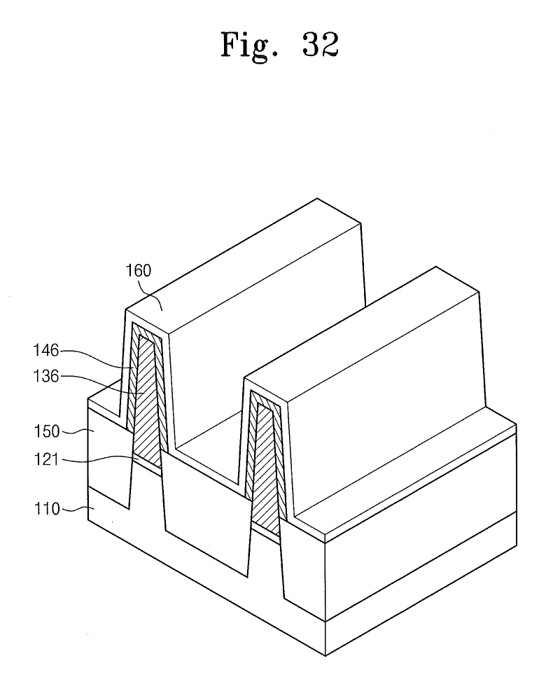

Referring to FIG. 32, a second insulation layer 160 may be formed on the device isolation layer 150, the preliminary floating gate 136, and the preliminary first semiconductor barrier pattern 146. The second insulation layer 160 may be an oxide layer, a nitride layer, or a stacked layer structure thereof. In some embodiments, the second insulation layer 160 may be an ONO layer. In other embodiments, the second insulation layer 160 may include a high-k layer having a higher dielectric constant than a nitride layer. For example, the second insulation layer 160 may include a metal oxide layer having high-k. For example, the second insulation layer 160 may include an aluminum oxide layer or a hafnium oxide layer. The second insulation layer 160 may be uniformly deposited on an uneven side of the preliminary floating gate 136.

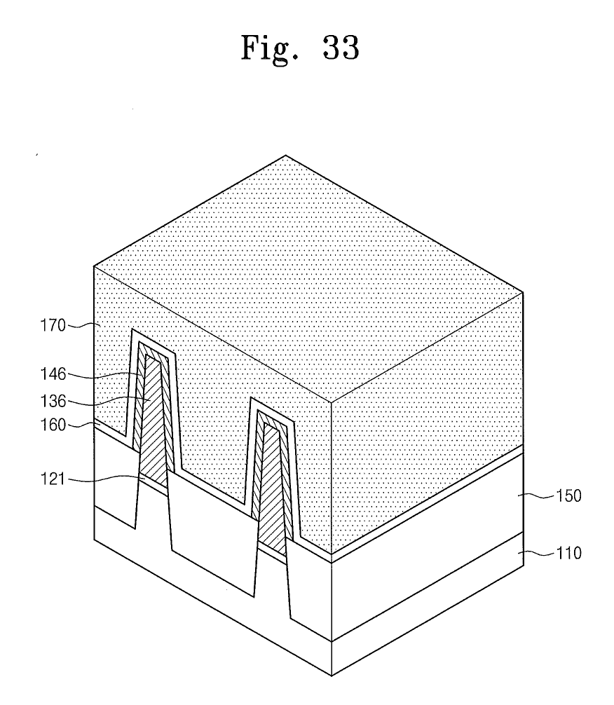

Referring to FIG. 33, a second conductive layer 170 may be formed on the second insulation layer 160. The second conductive layer 170 may be formed of a doped polysilicon layer or a doped polycide layer.

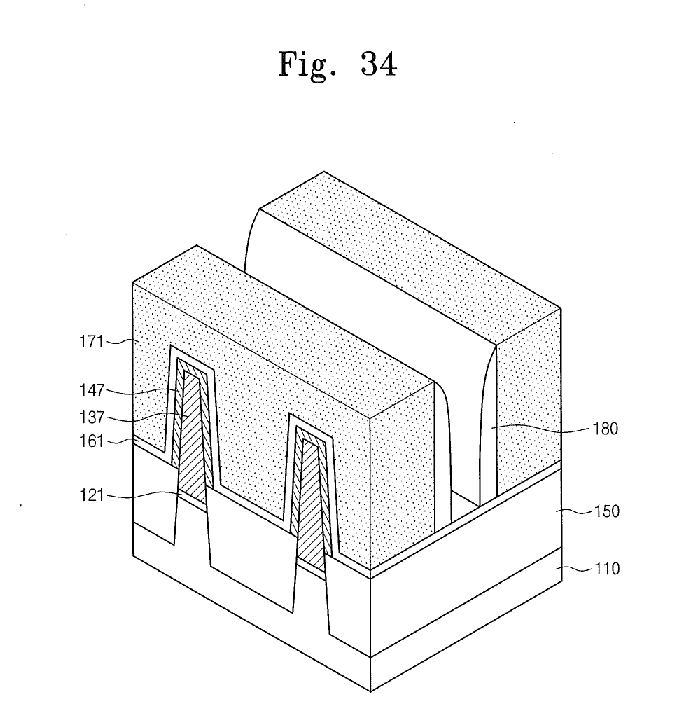

Referring to FIG. 34, the preliminary floating gate 136, the preliminary first semiconductor barrier pattern 146, the second insulation layer 160, and the second conductive layer 170 may be patterned. A floating gate 137, a first semiconductor barrier pattern 147, a blocking insulation layer 161, and a control gate 171 may be formed by the patterning. An insulation spacer 180 may be formed on the sidewall of the recessed region formed by the patterning. The insulation spacer 180 may be formed of a silicon nitride.

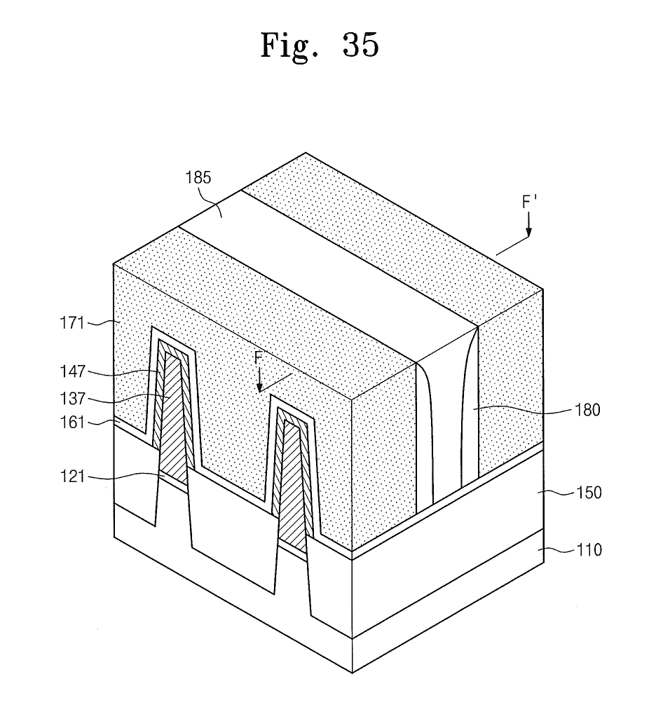

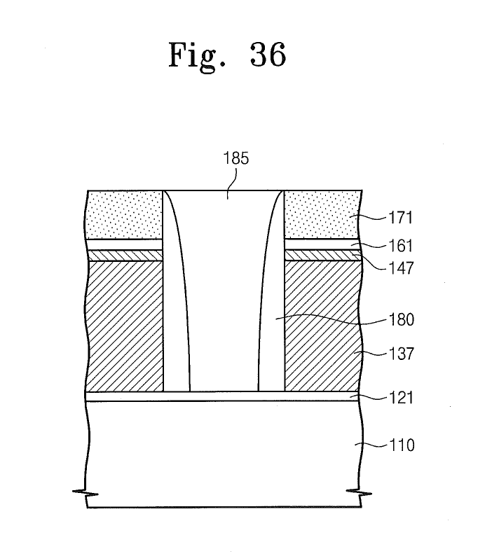

Referring to FIGS. 35 and 36, a third insulation layer 185 may be formed in the recessed region. The third insulation layer 185 may be a silicon oxide layer. FIG. 36 is a sectional view taken along the line F-F′ of FIG. 35.

In the non-volatile memory device according to the sixth embodiment of the inventive concept, the first semiconductor barrier pattern 147 extends on at least a portion of the top and sidewall of the floating gate 137. Accordingly, possibility of back tunneling to the blocking insulation layer 161 may be lowered by increasing the tunneling length. Thus, electric fields are concentrated on the top surface of the floating gate 137 such that leakage current increase through the blocking insulation layer 161 can be reduced and/or alleviated.

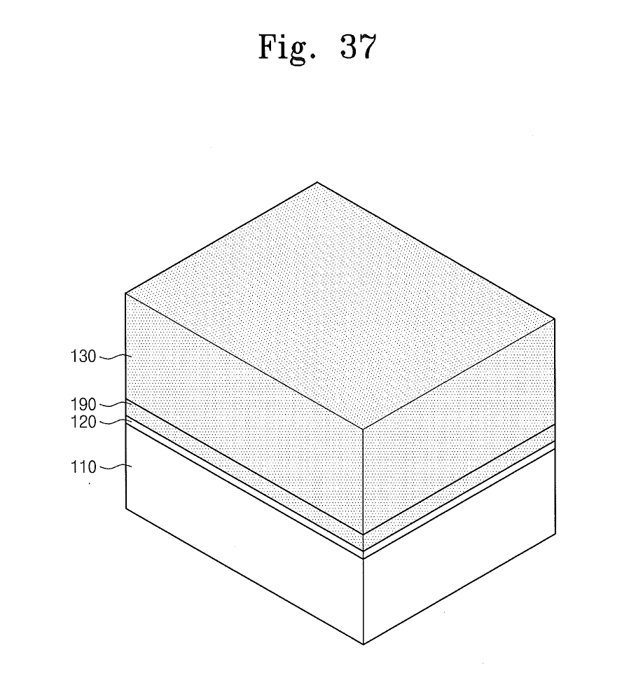

FIGS. 37 through 42 are views illustrating a non-volatile memory device and a method of forming the same according to a seventh embodiment of the inventive concept. Except for a difference of a method of forming the first semiconductor barrier pattern, this embodiment is similar to the first embodiment that is described above with respect to FIGS. 1-7. Accordingly, for conciseness of description, further discussion of overlapping technical features will be omitted.

Referring to FIG. 37, a first insulation layer 120 may be formed on a substrate 110. The first insulation layer 120 may include a silicon oxide layer. The first insulation layer 120 may be formed using a thermal oxidation process. A second semiconductor barrier layer 190 may be formed on the first insulation layer 120. The second semiconductor barrier layer 190 may be a P-type silicon layer. The second semiconductor barrier layer 190 may be formed, for example, by a CVD process. A first conductive layer 130 may be formed on the second semiconductor barrier layer 190. The first conductive layer 130 may be an N-type silicon layer. The first conductive layer 130 may also be formed by a CVD process.

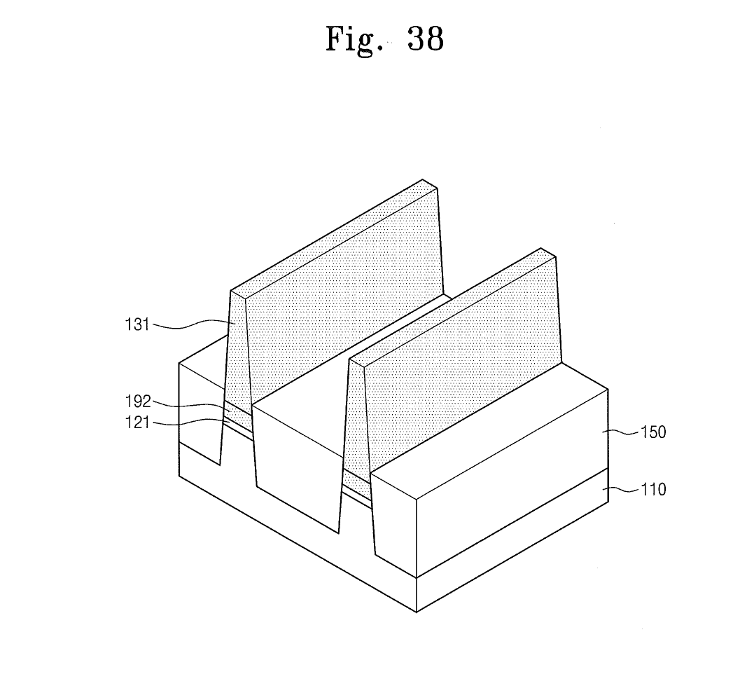

Referring to FIG. 38, the substrate 110, the first insulation layer 120, the second semiconductor barrier layer 190, and the first conductive layer 130 are patterned. A tunnel insulation layer 121, a preliminary second semiconductor barrier pattern 192, and a preliminary floating gate 131 are formed by the patterning. A device isolation layer 150 may be formed in a recessed region formed by the patterning.

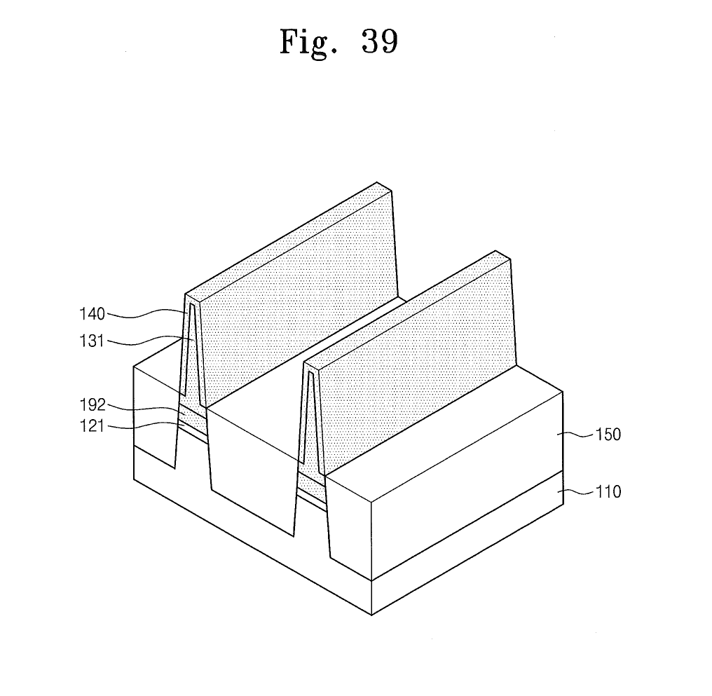

Referring to FIG. 39, a first semiconductor barrier layer 140 may be formed on the top and sidewall of the preliminary floating gate 131. The first semiconductor barrier layer 140 may be a P-type silicon layer. The first semiconductor barrier pattern 140 may be formed on the top and sidewall of the preliminary floating gate 131 by implanting a P-type impurity ion onto portions of the floating gate.

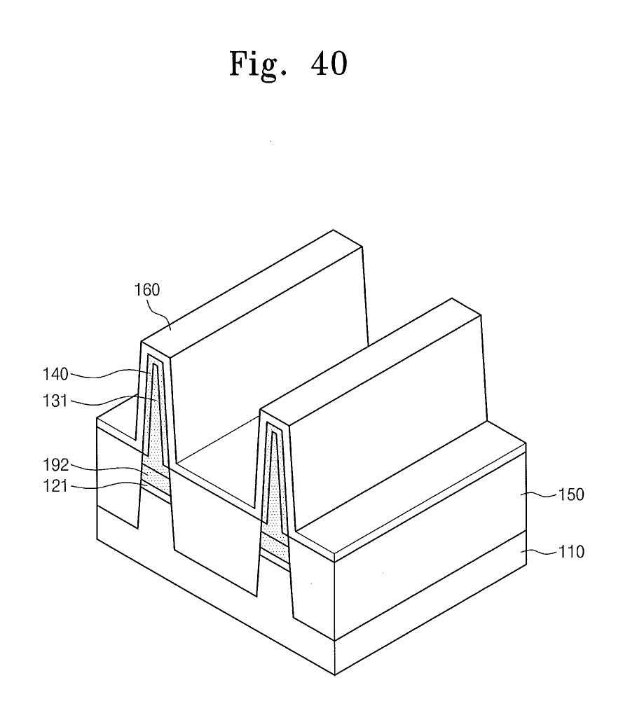

Referring to FIG. 40, a second insulation layer 160 may be formed on the device isolation layer 150, the preliminary floating gate 131, and the first semiconductor barrier layer 140. The second insulation layer 160 may be an oxide layer, a nitride layer, or a staked layer structure thereof. In some embodiments, the second insulation layer 160 may be an ONO layer. In other embodiments, the second insulation layer 160 may include a high-k layer having a higher dielectric constant than a nitride layer. For example, the second insulation layer 160 may include a metal oxide layer having a high-k. For example, the second insulation layer 160 may include an aluminum oxide layer or a hafnium oxide layer. The second insulation layer 160 may be uniformly deposited on an uneven side of the preliminary floating gate 131.

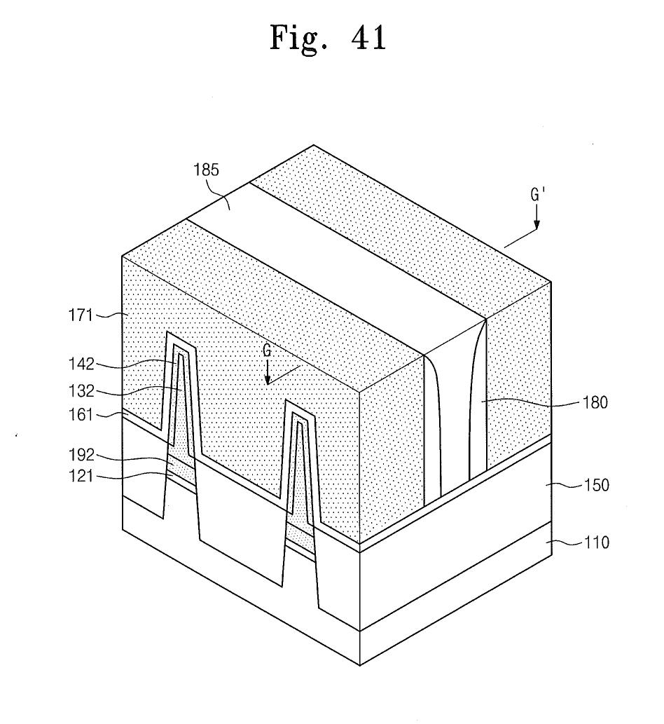

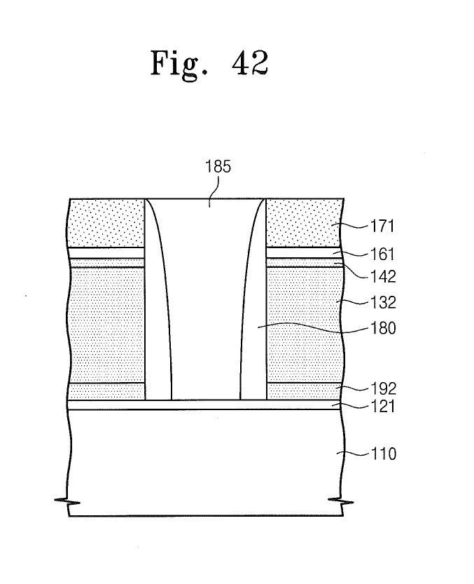

Referring to FIGS. 41 and 42, a second conductive layer (not shown) may be formed on the second insulation layer 160. The preliminary floating gate 131, the first semiconductor barrier layer 140, the second insulation layer 160, and the second conductive layer may be patterned. A floating gate 132, a first semiconductor barrier pattern 142, a blocking insulation layer 161, and a control gate 171 may be formed by the patterning. An insulation spacer 180 may be formed on the sidewall of the recessed region formed by the patterning. The insulation spacer 180 may be formed of a silicon nitride. A third insulation layer 185 may be formed in the remainder of the recessed region. The third insulation layer 185 may be a silicon oxide layer. FIG. 42 is a sectional view taken along the line G-G′ of FIG. 41.

The non-volatile memory device according to the seventh embodiment of the inventive concept may have an energy band of a well formed by the first semiconductor barrier pattern 142 and the second semiconductor barrier pattern 192. Accordingly, charges stored in the floating gate 132 may be more stably stored in the floating gate 132. Thus, reliability of the memory device can be improved.

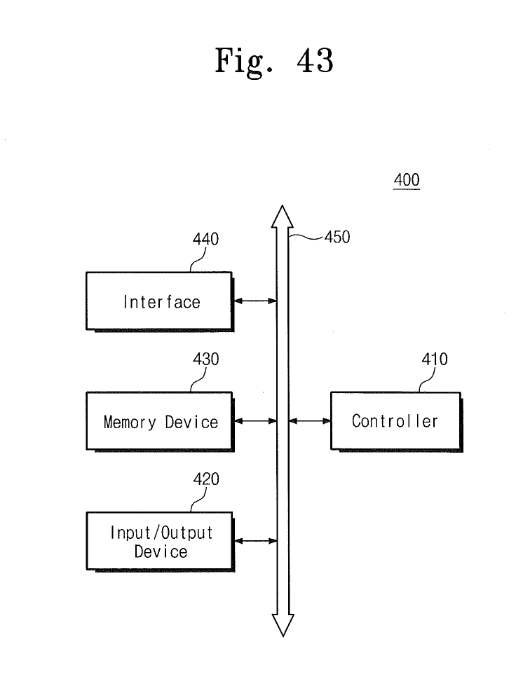

FIG. 43 is a block diagram illustrating an electronic system 400 including a non-volatile memory device 430 according to embodiments of the inventive concept.

Referring to FIG. 43, the electronic system 400 may include a controller 410, an input/output device 420, and the memory device 430. The controller 410, the input/output 420, and the memory device 430 are connected to each other through a bus 450. The bus 450 provides a path though which data can be transferred. The controller 410 may include at least one of a microprocessor, a digital signal processor, a microcontroller, and logic devices performing equivalent functions thereof. The input/output device 420 may include at least one of a keypad, a keyboard, and a display device. The memory device 430 stores data. The memory device 430 may store data and/or commands executed by the controller 410. The memory device 430 may include at least one of the non-volatile memory devices disclosed in the above embodiments. The electronic system 400 may further include an interface 440 for transmitting data to a communication network or external device or receiving data from a communication network or an external device. The interface 440 may comprise a wired or wireless interface. For example, the interface 440 may include an antenna or a wire/wireless transceiver.

The electronic system 400 may be realized with a mobile system, a personal computer, an industrial computer, or a system performing various functions. For example the mobile system may be a personal digital assistant (PDA), a portable computer, a web tablet, a mobile phone, a wireless phone, a laptop computer, a memory card, a camera, a digital music system, or an information transmitting/receiving system. If the electronic system 400 is a device for wireless communication, it may use, for example, a communication interface protocol of the third generation communication system such as code division multiple access (CDMA), global system for mobile communications (GSM), enhanced-time division multiple access (E-TDMA), wideband code division multiple access (W-CDMA), and CDMA1000.

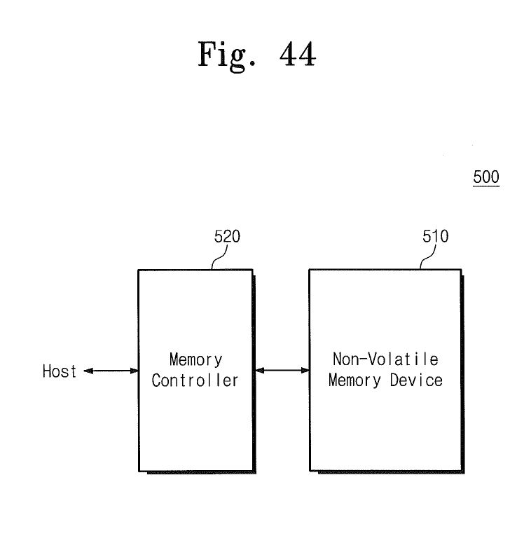

Next, a memory card including a non-volatile memory device according to an embodiment of the inventive concept will be described with reference to FIG. 44, which is a block diagram illustrating a memory card 500 including a non-volatile memory device 510 according to an embodiment of the inventive concept.

Referring to FIG. 44, the memory card 500 includes a non-volatile memory device 510 and a memory controller 520. Data can be written to, or read from, the non-volatile memory device 510. The non-volatile memory device 510 may include at least one of the non-volatile memory devices disclosed in the above embodiments. The memory controller 520 reads the stored data or controls the non-volatile memory device 510 to store data in response to a read/write request from a host.

According to the embodiments of the inventive concept, leakage current occurrence caused by electric field concentration can be alleviated by providing a semiconductor barrier layer between a floating gate and a blocking insulation layer. Additionally, reliability of a semiconductor device can be improved by providing a semiconductor barrier layer between a tunnel insulation layer and the floating gate.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

1. A non-volatile memory device comprising:
a first insulation layer on a substrate;
a floating gate on the first insulation layer;
a second insulation layer on the floating gate;
a first semiconductor barrier pattern, between a top of the floating gate and the second insulation layer, the first semiconductor barrier pattern having a higher conduction band energy level than the floating gate; and
a control gate on the second insulation layer.

2. The device of claim 1, wherein the first semiconductor barrier pattern extends on at least one side of the floating gate.

3. The device of claim 1, wherein a band gap of the first semiconductor barrier pattern is broader than that of the floating gate, wherein the first insulation layer comprises a tunnel insulation layer and the second insulation layer comprises a blocking insulation layer.

4. The device of claim 3, wherein the floating gate comprises germanium and the first semiconductor barrier pattern comprises silicon.

5. The device of claim 3, wherein the floating gate and the first semiconductor barrier pattern have the same conductivity type.

6. The device of claim 3, further comprising a second semiconductor barrier pattern between the tunnel insulation layer and the floating gate.

7. The device of claim 6, wherein the second semiconductor barrier pattern has a broader band gap than the floating gate.

8. The device of claim 7, wherein the second semiconductor pattern comprises silicon.

9. The device of claim 1, wherein the floating gate is an N-type semiconductor material and the first semiconductor barrier pattern is a P-type semiconductor material.

10. The device of claim 9, further comprising a second semiconductor battier pattern between the first insulation layer and the floating gate.

11. The device of claim 10, wherein the second semiconductor barrier pattern is formed of a P-type semiconductor material.

12-20. (canceled)
